(19) United States
(12) Patent Application Publication
(10) Pub. No.: US 2018/0138462 A1
(43) Pub. Date: May 17, 2018

(54) ORGANIC LIGHT EMITTING DIODE

(71) Applicant: SAMSUNG DISPLAY CO., LTD., Yongin-si (KR)

(72) Inventors: Jin Woo PARK, Yongin-si (KR); Wonjun SONG, Yongin-si (KR); Jihwan YOON, Yongin-si (KR); Myungjong JUNG, Yongin-si (KR); Keon Ha CHOI, Yongin-si (KR)

(21) Appl. No.: 15/869,821

(22) Filed: Jan. 12, 2018

Related U.S. Application Data
(63) Continuation of application No. 14/707,263, filed on May 8, 2015.

(30) Foreign Application Priority Data
Sep. 2, 2014 (KR) 10-2014-0116210

(51) Int. Cl. H01L 51/56; H01L 51/50; H01L 51/00

(52) U.S. Cl. CPC H01L 51/56; H01L 2251/5384; H01L 51/5016; H01L 51/0005; H01L 51/508; H01L 51/5092; H01L 51/0008

(57) ABSTRACT

An organic light emitting diode and a deposition system, the organic light emitting diode including a hole injection electrode; an electron injection electrode; and an electron transport layer between the hole injection electrode and the electron injection electrode, wherein the electron transport layer includes a first subsidiary layer formed of an electron injection material; and a second subsidiary layer formed by co-depositing the electron injection material and an electron transport material.

### CROSS-REFERENCE TO RELATED APPLICATIONS

This is a continuation application based on pending application Ser. No. 14/707,263, filed May 8, 2015, the entire contents of which is hereby incorporated by reference.

Korean Patent Application No. 10-2014-0116210, filed on Sep. 2, 2014, in the Korean Intellectual Property Office, and entitled: “Organic Light Emitting Diode,” is incorporated by reference herein in its entirety.

### BACKGROUND

### 1. Field

Embodiments relate to an organic light emitting diode.

### 2. Description of the Related Art

The next generation flat display devices include organic light emitting diode displays (OLED displays) that do not need additional light sources (different from liquid crystal displays (LCDs)) and that are superior to any other in luminance and viewing angle. Without an additional light source, the OLED displays may be fabricated in lighter and thinner dimensions. Moreover, the OLED displays are regarded as being characterized in lower power consumption, higher luminance, and higher response rate.

An OLED display may include an OLED including an anode, an organic light emission layer, and a cathode. The OLED emits light by means of excitons that are generated by injecting holes and electrons respectively from the anode and cathode and transited down to a ground state.

### SUMMARY

Embodiments are directed to an organic light emitting diode.

The embodiments may be realized by providing an organic light emitting diode including a hole injection electrode; an electron injection electrode; and an electron transport layer between the hole injection electrode and the electron injection electrode, wherein the electron transport layer includes a first subsidiary layer formed of an electron injection material; and a second subsidiary layer formed by co-depositing the electron injection material and an electron transport material.

The first subsidiary layer may be thinner than the second subsidiary layer.

The first subsidiary layer may have a thickness of about 3 Å to about 6 Å.

The electron transport layer may include a plurality of the first subsidiary layers and a plurality of the second subsidiary layers.

The first and second subsidiary layers may be alternately stacked to form the electron transport layer.

The electron injection material may be LiQ.

The embodiments may be realized by providing a deposition system for forming an electron transport layer on a deposition substrate, the system including a first evaporator to vaporize an electron injection material, the first evaporator being moveable along a predetermined direction; a first nozzle to eject the vaporized evaporative material to the deposition substrate, the first nozzle being at a top surface of the first evaporator; a second evaporator to vaporize an electron transport material, the second evaporator being moveable along the predetermined direction together with the first evaporator; a second nozzle to eject the vaporized electron transport material to the deposition substrate, the second nozzle being at a top surface of the second evaporator; and angling plates adjacent to the first and second nozzles, the angling plates directing the electron injection material from the first nozzle onto the deposition substrate at a first incident angle, and directing the electron transport material from the second nozzle onto the deposition substrate at a second incident angle, wherein the angling plates include a first angling plate between the first and second nozzles; and second angling plates at outer sides of the first and second nozzles, and wherein the first incident angle is larger than the second incident angle.

The first and second nozzles and the first and second angling plates may be moveable along the predetermined direction to form the electron transport layer on the deposition substrate.

The predetermined direction may be a direction from the first nozzle toward the second nozzle.

The deposition system may form an electron transport layer that includes a first subsidiary layer formed of the electron injection material; and a second subsidiary layer formed by co-depositing the electron injection material and the electron transport material.

The deposition system may form the first subsidiary layer thinner than the second subsidiary layer.

The deposition system may form the first subsidiary layer to have a thickness of about 3 Å to about 6 Å.

The embodiments may be realized by providing a deposition system forming an organic layer on a deposition substrate, the system including an evaporator to vaporize an evaporative material, the evaporator being moveable along a predetermined direction; a nozzle to eject the vaporized evaporative material to the deposition substrate, the nozzle being at a top surface of the evaporator; an angling plate to limit an incident angle at which the vaporized evaporative material is deposited onto the deposition substrate, the angling plate being adjacent to the nozzle; and an angling plate controller to control the angling plate and to control the incident angle to be a predetermined angle.

The deposition system may include a first evaporator to vaporize a first evaporative material, the first evaporator being moveable along the predetermined direction; a first nozzle to eject the vaporized first evaporative material, the first nozzle being at a top surface of the first evaporator; a second evaporator to vaporize a second evaporative material, the second evaporator being moveable along the predetermined direction; and a second nozzle to eject the vaporized second evaporative material, the second nozzle being at a top surface of the second evaporator.

The first evaporative material may include an electron injection material, and the second evaporative material may include an electron transport material.

The angling plate may include a first angling plate between the first and second nozzles.

The angling plate may include second angling plates at outer sides of the first and second nozzles and the first angling plate.

The angling plate controller may control the first and second angling plates such that the first evaporative material is introduced at a first incident angle onto the deposition substrate, and the second evaporative material is introduced at a second incident angle onto the deposition substrate.

The angling plate controller may control the first and second angling plates such that the first incident angle is larger than the second incident angle.

The first and second nozzles and the first and second angling plates may be coincidently moveable along the predetermined direction to form an electron transport layer on the deposition substrate.

The predetermined direction may be a direction from the first nozzle toward the second nozzle.

The deposition system may form an electron transport layer that includes a first subsidiary layer formed of the first evaporative material; and a second subsidiary layer formed by co-depositing the first and second evaporative materials.

The deposition system may form the first subsidiary layer thinner than the second subsidiary layer.

The deposition system may form the first subsidiary layer to have a thickness of about 3 Å to about 6 Å.

The deposition system may further include a third evaporator to vaporize a third evaporative material, the third evaporator being moveable along the predetermined direction; and a third nozzle to eject the vaporized third evaporative material, the third nozzle being at a top surface of the third evaporator.

The first evaporative material may include an electron characterized host, the second evaporative material may include a phosphorescent dopant, and the third evaporative material may include a hole characterized host.

The first to third nozzles may be sequentially arranged in correspondence with the first to third evaporators respectively, and a plurality of the angling plates may limit incident angles of the vaporized first to third evaporative materials, the plurality of angling plates being adjacent to the first to third nozzles.

The angling plate controller may control the angling plates such that the first evaporative material is introduced at a first incident angle onto the deposition substrate, the second evaporative material is introduced at a second incident angle onto the deposition substrate, and the third evaporative material is introduced at a third incident angle onto the deposition substrate.

The angling plate controller may control the angling plates such that the second incident angle is larger than the first incident angle or the third incident angle.

The deposition system may further include a slide shutter to control the third evaporative material to be deposited on the deposition substrate, the slide shutter being at a top side of the third nozzle.

The first to third nozzles and the angling plates may coincidently move along the predetermined direction, and the slide shutter may control the third evaporative material to be deposited such that the deposition system forms a multi-layered light emission layer.

The predetermined direction may be a direction from the first nozzle toward the third nozzle.

The deposition system may form a light emission layer that includes a first subsidiary layer formed by co-depositing the first and second evaporative materials; and a second subsidiary layer formed by co-depositing the second and third evaporative materials.

### BRIEF DESCRIPTION OF THE DRAWINGS

Features will be apparent to those of skill in the art by describing in detail exemplary embodiments with reference to the attached drawings in which:

FIG. 1 illustrates a deposition system for forming an electron transport layer;

FIG. 2 illustrates an OLED including the electron transport layer formed using the deposition system of FIG. 1;

FIG. 3A illustrates a table showing experimental data for light emission efficiencies of the OLED of FIG. 2;

FIG. 3B illustrates a graph showing experimental data for lifetimes of the OLED of FIG. 2;

FIG. 4 illustrates a deposition system for forming a light emission layer;

FIG. 5 illustrates a light emission layer formed using the deposition system of FIG. 4;

FIG. 6A illustrates a table showing experimental data for light emission efficiencies of OLEDs including the light emission layer of FIG. 5;

FIG. 6B illustrates a graph showing experimental data for lifetimes of OLEDs including the light emission layer of FIG. 5; and

FIGS. 7A to 7C illustrate light emission layers in diverse structures.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings herein.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “includes,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this application belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

A deposition system according to embodiments may include an evaporator to vaporize an evaporative material, a nozzle to eject the evaporative material onto a deposition substrate, and an angling plate to regulate or control an incident angle of the evaporative material.

The evaporator may include or accommodate the evaporative material therein. The evaporator may include a heater for vaporizing the evaporative material. The evaporator may vaporize the evaporative material by heating up the evaporative material using the heater. The nozzle may be at an outer, e.g., top, surface of the evaporator, and may eject the vaporized evaporative material (from the evaporator). The vaporized evaporative material ejected through the nozzle may then be deposited on the substrate. The substrate may be oppositely placed over the top side of the nozzle.

The deposition system may include at least an angling plate adjacent to the nozzle. The at least one angling plate may restrict an incident angle of the evaporative material that is ejected from the nozzle. The angling plate may be modifiable by physical dimensions or characteristics such as shape, placement, height, thickness, and so on in accordance with the properties of an organic layer. The physical characteristics and/or position of the angling plate may be automatically managed by an angling plate controller.

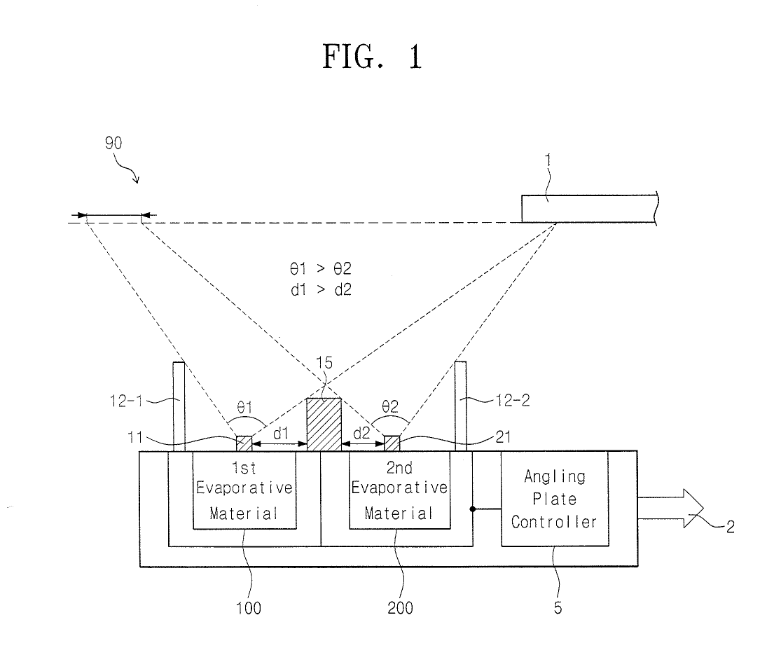

The nozzle and the angling plate may be together shifted, e.g., may be moveable, along a predetermined direction. For example, the nozzle and the angling plate may be shifted or moved in the predetermined direction on a position of the deposition substrate in order to form an organic layer as the evaporative material is deposited on the substrate. In an implementation, as shown in FIG. 1, if the substrate is placed at the right top side of the evaporator and the nozzle, the evaporator and the nozzle may be shifted or moveable to or toward the right side of FIG. 1. As a result, an organic layer made of or from the vaporized evaporative material may be formed on the substrate.

Descriptions about such elements of the deposition system may be all available in the deposition system described hereinafter and may not be further detailed in general for convenience of description.

FIG. 1 illustrates a deposition system for forming an electron transport layer.

Referring to FIG. 1, the deposition system 90 may include a first evaporator 100, a first nozzle 11, a second evaporator 200, a second nozzle 21, and first and second angling plates 15, 12-1, and 12-2.

The deposition system 90 may include the first evaporator 100 to vaporize a first evaporative material 10. The first evaporator 100 may include the first nozzle 11 at a surface thereof that faces the substrate, e.g., at the top surface of the first evaporator 100. The first nozzle 11 may eject the first evaporative material 10, which is vaporized by the first evaporator 100, to a deposition substrate 1. The deposition system 80 may include the second evaporator 200 to vaporize a second evaporative material 20. The second evaporator 200 may include the second nozzle 21 at a surface thereof that faces the substrate, e.g., at the top surface of the second evaporator 200. The second nozzle 21 may eject the evaporative material 20, which is vaporized, to the deposition substrate 1.

In an implementation, in the deposition system 90 for forming an electron transport layer, the evaporative material 10 may be an electron injection material (e.g. LiQ) and the second evaporative material 20 may be an electron transport material.

The deposition system 90 may employ first and second angling plates 15, 12-1 and 12-1, adjacent to the first and second nozzles 11 and 21, in order to limit incident angles of the first and second evaporative materials 10 and 20 (ejected from the nozzles) to the deposition substrate 1. For example, the first angling plate 15 may be between the first and second nozzles 11 and 21. The second angling plates 12-1 and 12-2 may be outside of the first and second nozzles 11 and 21 from the first angling plate 15, e.g., at outer sides of the respective first and second nozzles or evaporators.

The first and second angling plates 15, 12-1, and 12-2 (e.g., the first angling plate 15 and the second angling plate 12-1) may limit an incident angle of the first evaporative material 10 (ejected from the first nozzle 11) to be a first angle θ1. The first and second angling plates 15, 12-1, and 12-2 (e.g., the first angling plate 15 and the second angling plate 12-2) may limit an incident angle of the second evaporative material 20 (ejected from the second nozzle 21) to be a second angle θ2.

The first and second nozzles 11 and 21 may be shifted toward or moved along (e.g., may be moveable along) a predetermined direction 2, along with the first and second angling plates 15, 12-1, and 12-2, while ejecting the first and second evaporative materials 10 and 20, respectively. As a result, an electro transport layer made of the first and second evaporative materials 10 and 20 may be formed on the deposition substrate 1. The predetermined direction 2 may be a direction toward the second nozzle 21 from the first nozzle 11.

For example, the deposition system 90 according to an embodiment may form an electron transport layer that includes a first subsidiary layer (made of the first evaporative material 100) and a second subsidiary layer (in which the first and second evaporative materials 100 and 200 are compositively deposited or co-deposited). If the electron transport layer were to simply include the second subsidiary layer, an excessive number of carriers (incapable of generating excitons) could be created, thereby degrading a lifetime of the OLED. For example, the excess carriers may be holes.

As the deposition system 90 according to an embodiment operates to deposit the first subsidiary layer, which has a higher energy barrier, in addition to the electron transport layer, it is possible to restrict a flow of the excessive carriers in the electron transport layer. Therefore, the lifetime of the OLED may be lengthened.

To form the first subsidiary layer, the first angling plate 15 may limit the second incident angle θ2, e.g., an angle by or through which the second evaporative material 20 is introduced on or to the deposition substrate 1, to be larger than the first incident angle θ1, e.g., an angle by or through which the first evaporative material 10 is introduced on or to the deposition substrate 1. For example, the first incident angle θ1 may be larger than the second incident angle θ2. For example, the first evaporative material may be provided across a wider angle (first incident angle θ1) than the angle (second incident angle θ2) across which the second evaporative material is provided.

In an implementation, as shown in FIG. 1, the first angling plate 15 may be adjacent to the second nozzle 21. For example, a first distance d1 from the first nozzle 11 to the first angling plate 15 may be larger than a second distance d2 from the second nozzle 21 to the first angling plate 21. The first angling plate 15 may be adjacent to the second nozzle 21, and the second incident angle θ2 may be limited to be smaller or narrower than the first incident angle θ1.

In an implementation, the first angling plate 15 may be inclined toward the second nozzle 21. As the first angling plate 15 is inclined toward the second nozzle 21, the second incident angle may be limited to be smaller or narrower than the first incident angle.

In an implementation, the first angling plate 15 may be variously adjusted or modified in its physical dimensions and characteristics (e.g. shape, placement, height, thickness, etc.) so as to make the first incident angle θ1 larger or wider than the second incident angle θ2.

The physical characteristics of the first and second angling plates 15, 12-1, and 12-2 may automatically be adjusted by the angling plate controller 5. In an implementation, the angling plate controller 5 may regulate the physical dimensions or characteristics of the first angling plate 15 so as to introduce the first and second evaporative materials 10 and 20 into or onto the deposition substrate 1 at the first or second incident angles θ1 and θ2. For example, the angling plate controller 5 may shift or incline the first angling plate 15 toward the second nozzle 21. The angling plate controller 5 may be selectively included in the deposition system 90.

The first incident angle θ1 may be larger or wider than the second incident angle θ2, and thus the first subsidiary layer (formed of or including only the first evaporative material 10), and the second subsidiary layer (formed of or including a mix of the first and second evaporative materials 10 and 20), may be selectively formed on the deposition substrate 1. For example, the deposition system 90 may move along a predetermined direction and may deposit the first and second evaporative materials on the stationary deposition substrate. Accordingly, for a period of time, only the first evaporative material may be incident on the deposition substrate 1 (due to the wider first incident angle θ1) to form the first subsidiary layer including only the first evaporative material (without the second evaporative material). In addition, for a different period of time, both the first evaporative material and the second evaporative material may be incident on the deposition substrate 1 (e.g., a time period during which the first or second incident angles θ1 and θ2 are coextensive) to form the second subsidiary layer that includes the first and second evaporative materials.

With a view toward avoiding hindrance of electronic flow as well as excessive carriers, the first subsidiary layer may be formed thinner. In an implementation, the first subsidiary layer may have a thickness of, e.g., about 3 Å to about 6 Å. For example, a first thickness of the first subsidiary layer may be smaller than a second thickness of the second subsidiary layer.

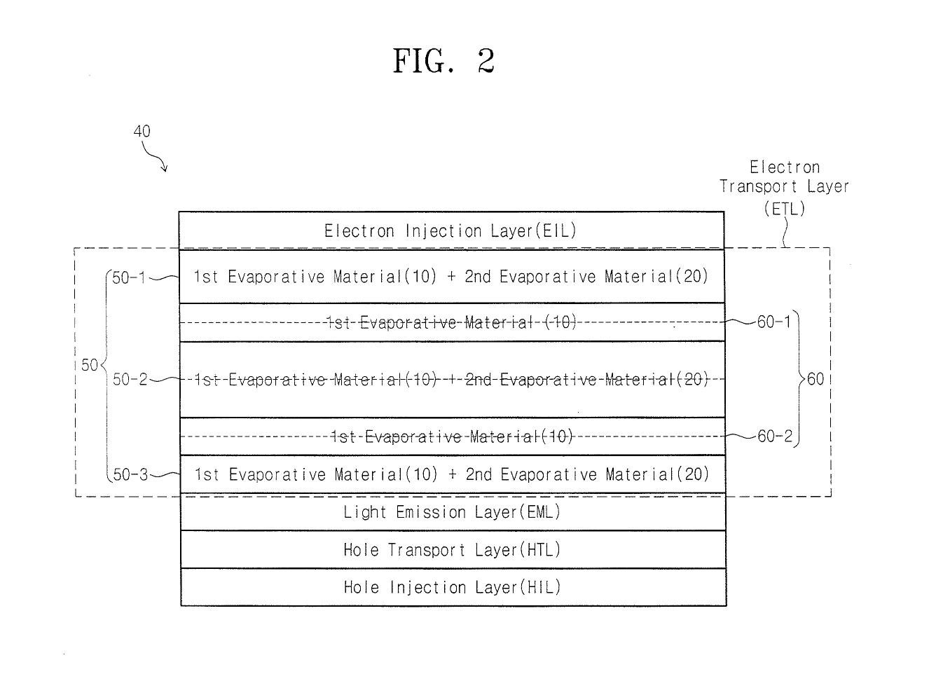

FIG. 2 illustrates an OLED including an electron transport layer prepared using the deposition system of FIG. 1.

Referring to FIG. 2, the OLED 40 may have a multi-layered structure including an electron injection layer EIL, an electron transport layer ETL, a light emission layer EML, and a hole transport layer HTL, stacked in order.

The electron transport layer ETL may be formed using the deposition system 90 aforementioned in conjunction with FIG. 1. Therefore, the electron transport layer ETL may be organized of or include multiple layers, e.g., including a first subsidiary layer 60 (prepared by depositing, e.g., only, the first evaporative material 10), and a second subsidiary layer 50 (prepared by co-depositing the first and second evaporative materials 10 and 20).

In an implementation, the electron transport layer ETL may be deposited while reciprocating the deposition system 90, and the first subsidiary layer(s) 60-1 and 60-2 and the second subsidiary layers 50-1 to 50-3 may be alternately deposited.

For example, the deposition system 90 may reciprocate one time (e.g., once out and back to its starting position). For example, the first and the second nozzles 11 and 21 and the first and second angling plates 14, 12-1, and 12-2 may coincidently move along a first direction 2, to deposit the second and first subsidiary layers 50-1 and 60-1 in sequence. Next, the first and the second nozzles 11 and 21, and the first and second angling plates 14, 12-1, and 12-2 may move along a second direction, which is reverse or opposite to the first direction 2, to, e.g., thickly, deposit the first subsidiary layer 60-1 and then additionally deposit the second subsidiary layer 50-2 on the first subsidiary layer 60-1 which has been, e.g., thickly, deposited. For example, by reciprocating one time, one of the first subsidiary layer 60-1 and two of the second subsidiary layers 50-1 and 50-2 may be alternately deposited. For example, as the deposition system 90 moves along the first direction, the first and second evaporative materials may be co-deposited to form the second subsidiary layer. When the deposition system 90 moves along the first direction far enough such that the second incident angle θ2 is no longer co-extensive with the deposition substrate (and the first incident angle θ1 remains co-extensive with the deposition substrate), formation of the second subsidiary layer may cease, and formation of the first subsidiary layer, including only the first evaporative material may commence. When the deposition system 90 reaches the end or limit of its reciprocation, the deposition system 90 may move in the second direction, and may continue depositing the first evaporative material to continue forming the first subsidiary layer. Once the deposition system 90 reaches a position such that the second incident angle θ2 is coextensive with the deposition substrate, co-deposition of the first and second evaporative materials may recommence, and an addition second subsidiary layer may be formed on the first subsidiary layer (e.g., the first subsidiary layer may be between two separate second subsidiary layers).

FIG. 2 illustrates a structure of the OLED 40 including the electron transport layer ETL prepared by reciprocating the deposition system 90 two times (e.g., out and back and out and back). This two time reciprocation makes it possible to form the electron transport layer ETL including two of the first subsidiary layers 60-1 and 60-2, and three of the second subsidiary layers 50-1, 50-2, and 50-3 that are alternately stacked.

The number of reciprocation of the deposition system 90 may be determined or selected in various ways based upon desired structures of the OLED and the organic layer to be deposited.

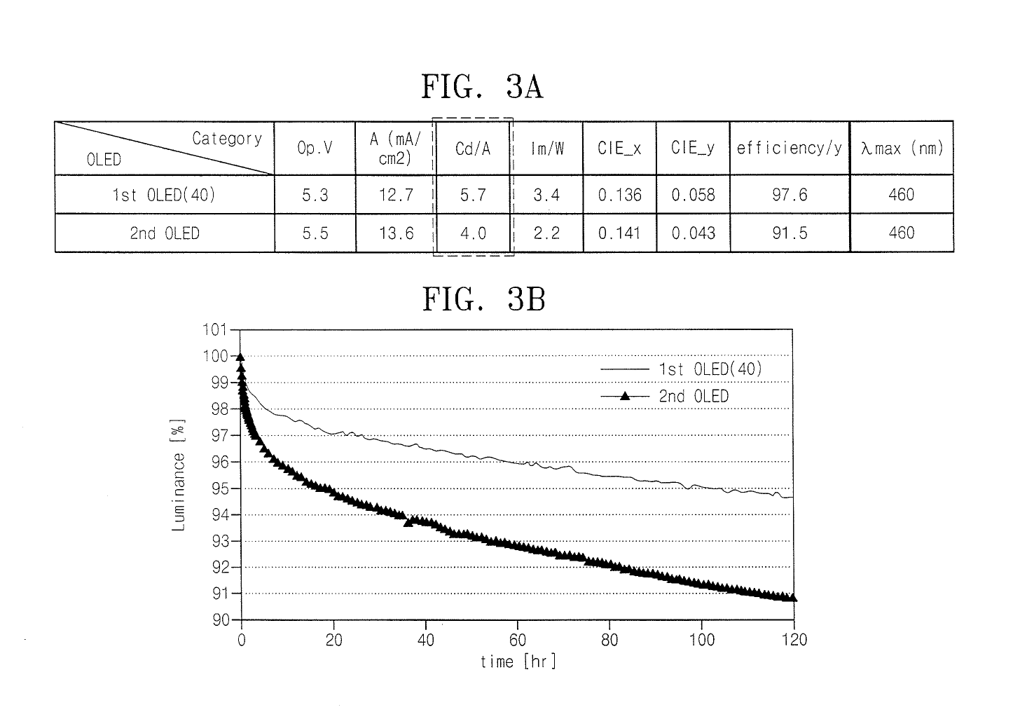

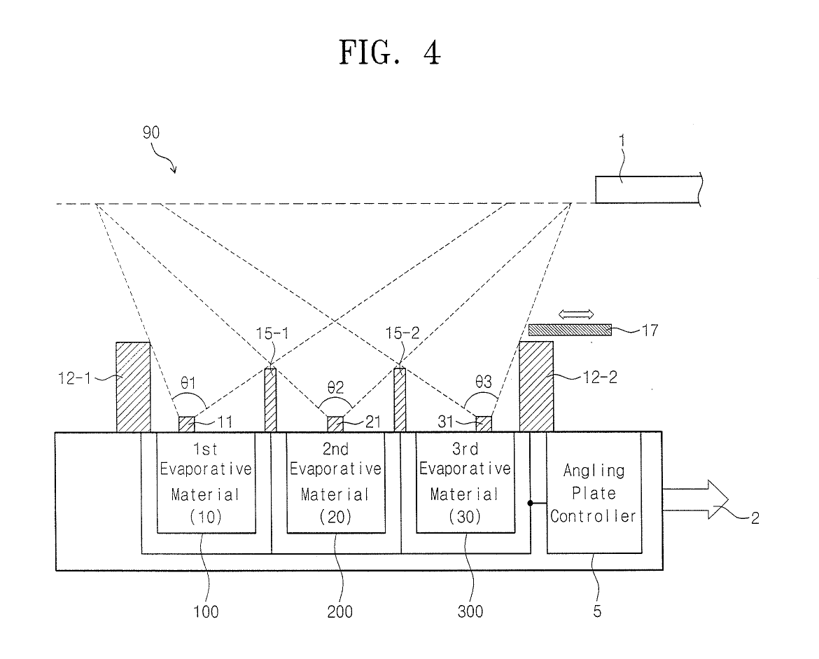

FIG. 3A illustrates a table showing experimental data for light emission efficiencies of the OLEDs of FIG. 2.

Referring to FIG. 3A, the first OLED (including the first and second subsidiary layers 50 and 60 within its electron transport layer ETL) may be higher in light emission efficiency than the second OLED (including only the second subsidiary layer 50 in its electron transport layer). For example, for the reference index Cd/A that denotes the light emission efficiency, the first OLED 40 may have 5.7 Cd/A while the second OLED had 4.0 Cd/A. This means that the first OLED 40 may be higher in light emission efficiency than the second OLED by 1.7 Cd/A.

FIG. 3B illustrates a graph showing experimental data for lifetimes of the OLEDs of FIG. 2. A lifetime of OLED may represent a time until when an OLED comes to have a predetermined level of light emission efficiency.

As can be seen from FIG. 3B, the first OLED 40 may be longer than the second OLED in taking a time for reducing their light emission efficiency to the same level. For example, looking at the time it takes for the light emission efficiency to be reduced to 90%, the first OLED 40 make take about 60 hours and the second OLED may take only about 10 hours.

For example, it may be seen from the experimental graph that the first OLED 40 may have a longer lifetime than the second OLED. This may be because the first subsidiary layer 60 included in the first OLED 40 may help control or reduce excessive carriers, e.g., as described in conjunction with FIG. 1.

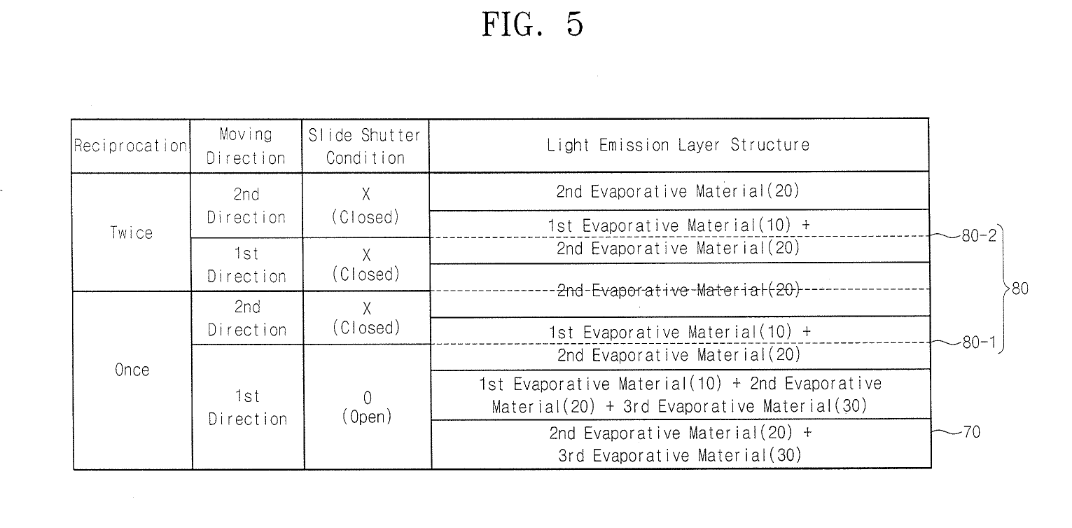

FIG. 4 illustrates a deposition system for forming a light emission layer. As the elements commonly illustrated in FIGS. 1 and 4 may be substantially described in the same feature as formerly done with FIG. 1, they may not be duplicated.

Referring to FIG. 4, the deposition system 90 may include first to third evaporators 100, 200, and 300, first to third nozzles 11, 21, and 31, and a plurality of angling plates 12-1, 15-1, 15-2, and 12-2.

The deposition system 90 according to the present embodiment may further include the third evaporator 300 to vaporize a third evaporative material 30, in addition to the first and second evaporators 100 and 200. The third evaporator 300 may be equipped with the third nozzle 31 at an outer surface thereof that faces a deposition substrate, e.g., at its top surface. The third nozzle 31 may eject the third evaporative material 30, which is vaporized in the third evaporator 300, onto the deposition substrate 1. The first to third evaporators 100, 200, and 300 may be sequentially arranged, and thus the first to third nozzles 11, 21 and 31 may be also arranged in sequence.

The deposition system 90 according to the present embodiment may be used to prepare a light emission layer EML of an OLED device. In an implementation, the first evaporative material 10 may be, e.g., an electron characterized host, the second evaporative material 20 may be, e.g., a phosphorescent dopant, and the third evaporative material 30 may be, e.g., a hole characterized host. For example, the first evaporative material 10 may be a first green phosphorescent dopant with a higher rate of the electron characterized host, the second evaporative material 20 may be a green phosphorescent dopant, and the third evaporative material 30 may be a second green phosphorescent dopant with a higher rate of the hole characterized host.

The deposition system 90 may form a light emission layer EML including a plurality of layers with different ratios between the first and third evaporative materials 10 and 30 in order to help improve the light emission efficiency. For example, the deposition system 90 may be sued to prepare a light emission layer by alternately stacking a first subsidiary layer (including the first and second evaporative materials 10 and 20) and a second subsidiary layer (including second and third evaporative materials 20 and 30).

To form a multi-layered light emission layer, the first and second angling plates 12-1, 15-1, 15-2, and 12-2 may be placed adjacent to the first to third nozzles 11, 21, and 31. The first angling plates 15-1 and 15-2 of the plurality of angling plates 12-1, 15-1, 15-2, and 12-2 may be disposed between the first and second nozzles 11 and 21 and between the second and third nozzles 21 and 31, respectively. The second angling plates 12-1 and 12-2 of the plurality of angling plates 12-1, 15-1, 15-2, and 12-2 may be disposed outside of the first and third nozzles 11 and 31, respectively, from the first angling plates 15-1 and 15-2. For example, the second angling plates 12-1 and 12-2 may be at outermost sides of the first and third nozzles 11 and 31, respectively.

The first and second angling plates 12-1, 15-1, 15-2, and 12-2 may limit an incident angle (by or at which the first evaporative material 10 is introduced into or onto the deposition substrate 1) to be a first incident angle θ1. Additionally, the first and second angling plates 12-1, 15-1, 15-2, and 12-2 may limit an incident angle (by or at which the second evaporative material 20 is introduced into or onto the deposition substrate 1), to be the second incident angle θ2. The first and second angling plates 12-1, 15-1, 15-2, and 12-2 may limit an incident angle (by or at which the third evaporative material 30 is introduced into or onto the deposition substrate 1) to be the third incident angle θ3. For example, the second incident angle θ2 may be larger or wider than the first and/or third incident angle θ1 and/or θ3. In an implementation, the incident angles may be limited as described above in conjunction with FIG. 1.

The deposition system 90 may shift or move the first to third nozzles 11, 21, and 31 together the angling plates 12-1, 15-1, 15-2, and 12-2 toward or along the first direction 2. In an implementation, the first direction 2 may be a direction toward or to the third nozzle 31 from the first nozzle 11. In an implementation, the deposition system 90 may move the first to third nozzles 11, 21 and 31 together with the angling plates 12-1, 15-1, 15-2 and 12-2 along the second direction, which is reverse or opposite to the first direction 2. For example, the second direction may be the direction toward or to the first nozzle 11 from the third nozzle 31.

The deposition system 90 may include a slide shutter 17 for stacking or forming a layer with different ratios of the first and third evaporative materials 10 and 30. The slide shutter 17 may be placed at a substrate (e.g., top) side of the third nozzle 31, and may control the deposition of the third evaporative material 30 by horizontal reciprocation.

For example, if the deposition system 90 closes the slide shutter 17, the slide shutter 17 moves along a first horizontal direction (e.g., the first or second direction) to interrupt or block an ejection path of the third nozzle 31 and then shut or cut off the deposition of the third evaporative material 30. If the deposition system 90 opens the slide shutter 17, the slide shutter 17 moved along a second horizontal direction, which is reverse or opposite to the first horizontal direction, to enable or open the ejection path of the third nozzle 31.

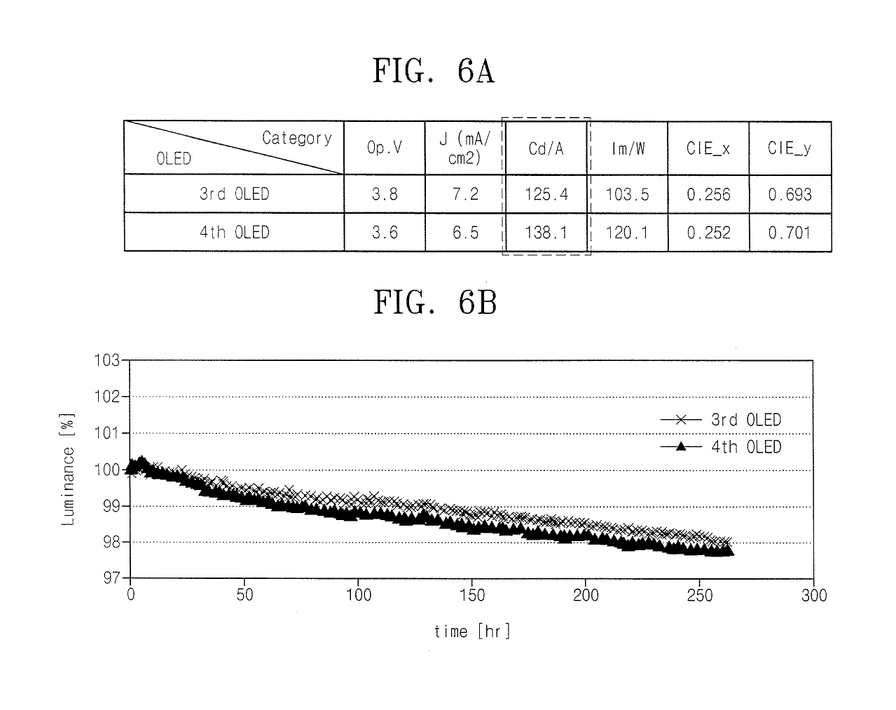

The deposition system 90 may control the slide shutter 17 while forcing the first to third nozzles 11, 21, and 31 and the angling plates 12-1, 15-1, 15-2, and 12-2 to move in reciprocation, thus resulting in a light emission layer EML which is formed of a plurality of layers with different ratios of the first and third evaporative materials 10 and 30. A multi-layered structure of the light emission layer EML will be described in greater detail below in conjunction with FIG. 5.

In an implementation, the deposition system 90 may further include an angling plate controller 5. The angling plate controller 5 may adjust the physical characteristics, e.g., shape, size, arrangement, position, or the like, of the angling plates 12-1, 15-1, 15-2, and 12-2 in accordance with the property of the organic layer to be deposited. For example, if the light emission layer EML is to be formed after depositing the electron transport layer ETL, the angling plate controller 5 may increase a number of the angling plates 12-1, 15-1, 15-2, and 12-2, and adjust their heights and intervals therebetween. Therefore, the deposition system according to this embodiment may be similar to the deposition system 90 shown in FIG. 1.

FIG. 5 illustrates a light emission layer prepared using the deposition system of FIG. 4.

Referring to FIG. 5, the light emission layer EML may include a first subsidiary layer 80 formed of the first and second evaporative materials 10 and 20, and a second subsidiary layer 70 formed of the second and third evaporative materials 20 and 30. In an implementation, the light emission layer EML may further include a subsidiary layer formed of the second evaporative material 20, and/or a subsidiary layer formed of the first to third evaporative materials 10, 20 and 30.

First, while the slide shutter 17 is open, the deposition system 90 may shift or move the first to third nozzles 11, 21, and 31, together with the angling plates 12-1, 15-1, 15-2, and 12-2, along the first direction 2. According, the second subsidiary layer 70 (including the co-deposited second and third evaporative materials 20 and 30), a subsidiary layer (including the co-deposited first to third evaporative materials 10, 20 and 30), and the first subsidiary layer 80-1 (including the co-deposited first and second evaporative materials 10 and 20) may be sequentially stacked on the deposition substrate 1.

Next, while the slide shutter 17 is closed, the deposition system 90 may move the first to third nozzles 11, 21, and 31, together with the angling plates 12-1, 15-1, 15-2, and 12-2, along the second direction. Accordingly, the first subsidiary layer 80-1 (which has been previously stacked) may be additionally deposited (e.g., thickened), and a subsidiary layer (including the deposited second evaporative material 20) may be stacked thereon in sequence.

Next, while the slide shutter 17 is still closed, the deposition system 90 may move the first to third nozzles 11, 21, and 31, together with the angling plates 12-1, 15-1, 15-2, and 12-2, along the first direction 2 again. Accordingly, the subsidiary layer formed of the second evaporative material 20 may be additionally deposited, e.g., thickened, and the first subsidiary layer 80-2 (including the co-deposited first and second evaporative materials 10 and 20) may be sequentially stacked on the subsidiary layer corresponding thereto.

Finally, while the slide shutter 17 is closed, the deposition system 90 may move the first to third nozzles 11, 21, and 31, together with the angling plates 12-1, 15-1, 15-2, and 12-2, along the second direction again. Accordingly, on the subsidiary layer 80-3 which has been previously stacked, there may be sequentially stacked the first subsidiary layer 80-4 (including the co-deposited first and second evaporative materials 10 and 20), and a subsidiary layer (including the deposited second evaporative material 20).

By alternately stacking the first subsidiary layer 80 (including the electron characterized host) and the second subsidiary layer 70 (including the hole characterized host), light emission at the interface of the hole transport layer HTL and the light emission layer EML may be migrated into the light emission layer EML, thereby improving the light emission efficiency.

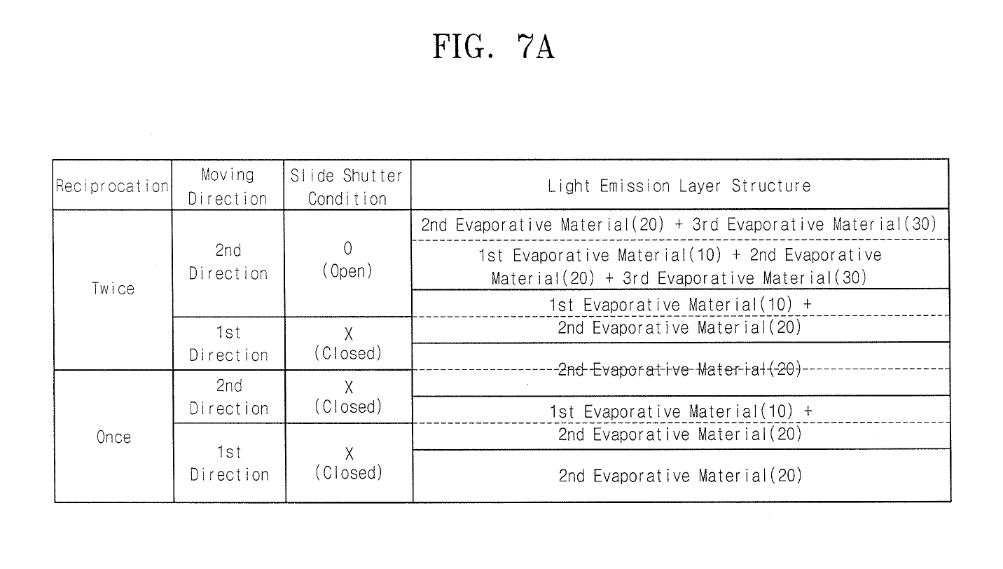

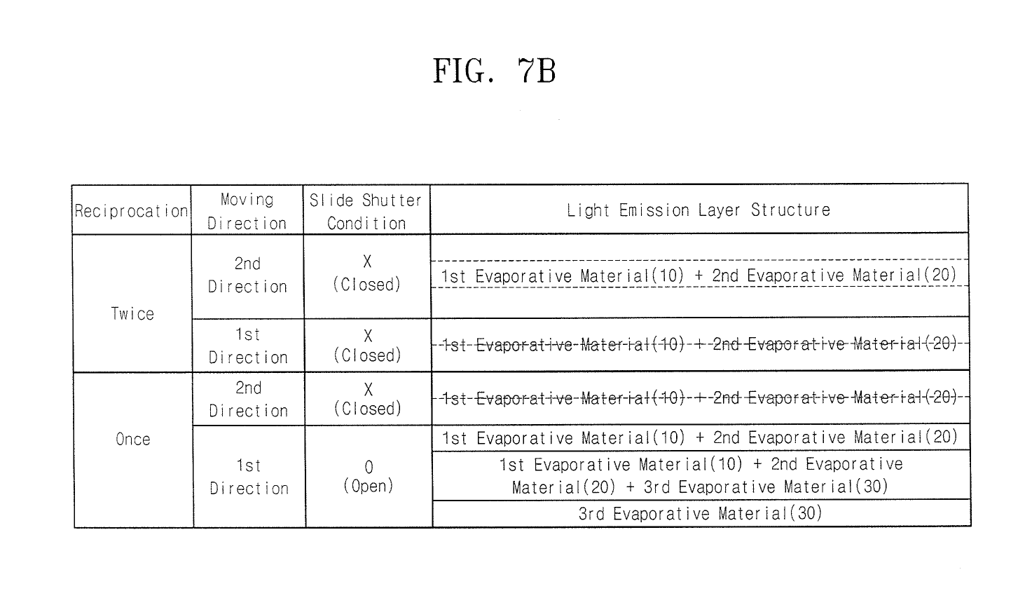

FIG. 6A illustrates a table showing experimental data for light emission efficiencies of the OLED including the light emission layers of FIG. 5.

Referring to FIG. 6A, it may be seen that the fourth OLED may have a higher light emission efficiency than the third OLED. The fourth OLED is a device including the light emission layer EML of FIG. 5, and the third OLED is a device including a light emission layer where the first to third evaporative materials 10, 20 and 30 are co-deposited to be a single layer.

For example, for the reference index Cd/A denoting the light emission efficiency, the third OLED may have 125.4 Cd/A and the fourth OLED may have 138.1 Cd/A. Therefore, the fourth OLED may be higher than the third OLED by 12.7 Cd/A in light emission efficiency.

FIG. 6B illustrates a graph showing experimental data for lifetimes of the OLED including the light emission layers of FIG. 5.

From the graph of FIG. 6B, it may be seen that there was a mere difference between the third and fourth OLEDs in lifetime.

As shown in FIGS. 6A and 6B, the fourth OLED may be almost same with the third OLED in lifetime, whereas the fourth OLED may be higher than the third OLED in light emission efficiency. This is because light emission of the fourth OLED may be enabled in the light emission layer EML, including the first and second subsidiary layers 70 and 80.

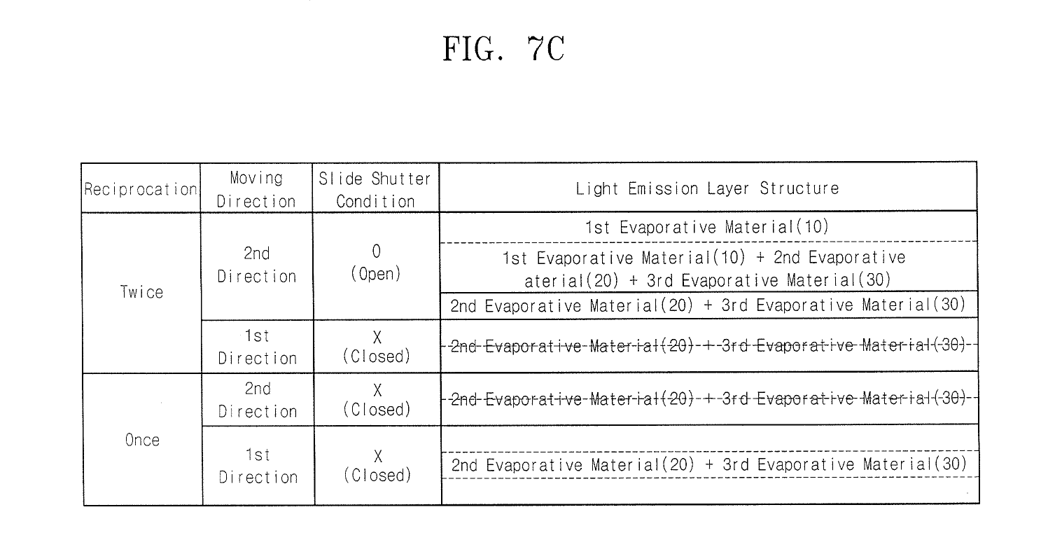

FIGS. 7A to 7C illustrate light emission layers in diverse structures.

Referring to FIG. 7A, the light emission layer EML may be prepared using the deposition system 90 of FIG. 4. In an implementation, the first evaporative material 10 may be a hole characterized host, the second evaporative material 20 may be a phosphorescent dopant, and the third evaporative material 30 may be an electron characterized host. The deposition system 90 according to this embodiment may form the light emission layer of FIG. 7 by opening the slide shutter 17 when moving toward the second direction during the second reciprocation.

Referring to FIG. 7B, this light emission layer may also be prepared suing the deposition system of FIG. 4. In an implementation, the first angling plate 15-2 between the second and third nozzles 21 and 31 may be placed to more or further limit or narrow the second incident angle θ2 than the first angling plate 15-2 of FIG. 4. This is for forming a subsidiary layer, which is simply made of or includes only the second evaporative material 20, not to be formed in the light emission layer. The deposition system 90 of FIG. 7B may generate the light emission layer shown in FIG. 7B by opening the slide shutter 17 when moving along the first direction 2 during the first reciprocation.

Referring to FIG. 7C, this light emission layer may also be prepared suing the deposition system 90 of FIG. 4. In an implementation, the slide shutter 17 may control the deposition of the first evaporative material 10, and the first angling plate 15-1 between the first and second nozzles 11 and 21 may more or further limit or narrow the second incident angle θ2 relative to the first angling plate 15-2 of FIG. 4. The deposition system 90 of FIG. 7C may form the light emission layer shown in FIG. 7C by opening the slide shutter 17 while moving along the second direction during the second reciprocation.

The light emission layers shown in FIGS. 7A to 7C may also be effective in improving the light emission efficiency, including the first and second subsidiary layers.

By way of summation and review, an anode and cathode may be formed of metallic or conductive films. The organic light emission layer may be formed by depositing at least a single layer of organic film. A deposition system may be employed to form an organic film, a metallic film, and so forth on a substrate for the OLED display. Such a deposition system may have an evaporator for containing an evaporative material and a nozzle for ejecting the evaporative material. If the evaporator is heated up to predetermined temperature, the evaporative material of the evaporator may be vaporized and ejected from the nozzle. Accordingly, as the evaporative material ejected from the nozzle is deposited on the substrate, a thin film may be formed thereon.

The embodiments may provide a multi-layered organic emitting diode and a deposition system therefor.

The embodiments may provide an OLED with a structure that is improved in light emission efficiency and lifetime.

As described above, the OLED according to the embodiments may be effective in improving its lifetime by generating the electron transport layer which is formed of electron injection material.

Moreover, the OLED according to the embodiments is advantageous to enhancing light emission efficiency thereof by forming the light emission layer to include a plurality of layers that are different from each other in ratios between the electron and hole characterized hosts.

In this specification, the values about length, direction, and location mean substantially practical dimensions and may be permitted with predetermined deviations.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1.-20. (canceled)

21. A organic light emitting diode comprising:
a hole injection electrode;
an electron injection electrode;
a light emitting layer disposed between the hole injection electrode and the electron injection electrode, and
an electron transport layer disposed between the hole injection electrode and the light emitting layer, and comprising a first subsidiary layer including an electron injection material and a second subsidiary layer in which the electron injection material and electron transport material are mixed
wherein the electron injection material is vaporized by a first evaporator and provided by a first nozzle
wherein the electron transport layer is vaporized by a second evaporator and provided by a second nozzle.

22. The organic light emitting diode as claimed in claim 21,
wherein a thickness of the first subsidiary layer is smaller than a thickness of the second subsidiary layer.

23. The organic light emitting diode as claimed in claim 21,
wherein the first subsidiary layer has a thickness of 3 Å to 6 Å.

24. The organic light emitting diode as claimed in claim 21,
wherein the electron transport layer comprises a plurality of the first subsidiary layer and a plurality of the second subsidiary layer.

25. The organic light emitting diode as claimed in claim 24,
wherein the electron transport layer is formed by alternately stacked by first subsidiary layer and the second subsidiary layer.

26. The organic light emitting diode as claimed in claim 21,
wherein the electron injection material is LiQ.
